(19) United States
(12) Patent Application Publication
(10) Pub. No.: US 2023/0184852 A1
(43) Pub. Date: Jun. 15, 2023

(54) Sensor, magnetic field position measuring system and method for determining position

(71) Applicant: Balluff GmbH, Neuhausen a.d.F. (DE)

(72) Inventors: Matthias Niethammer, Stuttgart (DE); Ulrich Ritter, Tubingen (DE); Christoph Boeckenhoff, Neuhausen (DE)

(21) Appl. No.: 18/075,931

(22) Filed: Dec. 6, 2022

(30) Foreign Application Priority Data
Dec. 14, 2021 (DE) 10 2021 132 974.4

(51) Int. Cl. G01R 33/032; G01D 5/14

(52) U.S. Cl. CPC G01R 33/032; G01D 5/14

(57) ABSTRACT

A sensor (10) for a magnetic field position measuring system has at least one transparent substrate (11) that has a first side and a second side which is opposite the first side. At least one photosensor (12) using spatial resolution is arranged on the second side. At least one light source (13a-h) is arranged on at least one side. Diamonds (14) having lattice defects are arranged between the substrate (11) and the photosensor (12) and/or in the substrate (11). Alternatively, the substrate (11) is a diamond having lattice defects.

The present invention relates to a sensor for a magnetic field position measuring system. The present invention also relates to a magnetic field position measuring system having the sensor. Finally, the present invention relates to a method for determining position by means of the magnetic field position measuring system.

### PRIOR ART

Different operating principles are used for displacement sensors and spacing sensors in industrial automation. Magnetic measuring bodies that are magnetised with a changing polarity are widely used in many applications due to their robustness and arbitrary location. A sensor is moved over these magnetic measuring bodies in order to thus implement a magnetic field position measuring system in the form of a magnetically coded length measuring system. The AMR effect, the GMR effect or the TMR effect is used to detect the relative movement between the sensor and the measuring body. The AMR effect (anisotropic magnetoresistance effect) causes a ferromagnetic metal in the sensor, said metal having its own magnetisation, to show an electrical resistance which is dependent on the outer magnetic field. The GMR effect (giant magnetoresistance) is a quantum mechanical effect which is observed in structures consisting of alternating magnetic and non-magnetic thin layers having their own layer thickness in nanometres. The electrical resistance of the structure depends on the mutual orientation of the magnetisation of the magnetic layers, wherein said electrical resistance is significantly higher for magnetisation in opposite directions than for magnetisation in the same direction. The TMR effect (tunnel magnetoresistance) is used in magnetic tunnel contacts. These have several layers arranged one above the other, in the core of which there are two ferromagnetic layers whose magnetisation direction can be switched by an external magnetic field independently of one another. If the magnetisations are aligned in the same way, then the probability that the electrons tunnel through the insulation layer is greater than in an opposed alignment. The electrical resistance of the contact can thus be switched back and forth between two different resistance states. When the AMR effect, GMR effect or TMR effect is used, when the sensor is moved along the measuring body, a sinusoidal sensor signal is ideally generated, whose signal profile in the sensor repeats with every pole of the measuring body. If a Hall sensor is used, however, then the signal profile in the sensor repeats with every pole pair of the measuring body. A position is determined, for example, by means of trigonometric functions, in which two sensor elements signal offset by 90° are used.

In order to suppress tolerances, temperature effects and signal noise, and to maintain a maximum linearity of the sensor signal, sensors of this kind are mostly adjusted for a fixed pole width of the measuring body. Several sensors are arranged in such a way that it is possible to measure at different positions, and thus at different poles at once. However, magnetic field position measuring systems of this kind are limited with regards to the maximum spacing between the measuring body and the sensor.

DE 10 2020 109 477 A1 describes the production of diamonds having a high concentration of NV defects (nitrogen vacancy) with the aim of usage in sensor systems and associated methods and devices.

It is an object of the present invention to provide a sensor and a magnetic field position measuring system that uses this sensor that can tolerate a greater spacing between sensor and measuring body than is possible for conventional magnetic field position measuring systems based on the AMR effect, the GMR effect or the TMR effect, or that use Hall sensors. The precision of the sensor should additionally be increased in comparison with these known types of sensor, and the occurrence of hysteresis effects should be avoided. A further object of the invention is to provide a method for determining position by means of the magnetic field position measuring system.

### DISCLOSURE OF THE INVENTION

This object is solved in a first aspect of the invention by a sensor for a magnetic field position measuring system having at least one transparent substrate. The substrate has a first side and a second side which is opposite the first side. In principle, the substrate can have any geometric shape. Preferably, however, it has several third sides and in particular it is preferably rectangular, such that it has four third sides. The first side is provided to face a magnet in the magnetic field position measuring system. At least one photosensor using spatial resolution is arranged on the second side. At least one light source is arranged on at least one side. Diamonds having lattice defects are arranged between the substrate and the photosensor and/or in the substrate. The substrate is alternatively or additionally a diamond having lattice defects.

A transparent substrate is in particular understood as a substrate whose light absorption in the visible region of the light spectrum amounts to a maximum of 10% from 380 nm to 780 nm. The light absorption can in particular be determined according to Norm ISO 13468-1. Suitable transparent materials for the substrate are, for example, glass, polycarbonate (PC) or polymethylmethacrylate (PMMA). If diamonds are arranged in the substrate, then the substrate can in particular be produced by mixing the diamonds with a molten form of the substrate material, and then by shaping the substrate, for example via casting or by means of injection moulding. If diamonds are arranged between the substrate and the photosensor, then, for example, they can be suspended in a liquid, which is then sprayed onto the second side of the substrate, or onto the side of the photosensor that is facing the second side of the substrate. After the liquid evaporates, a layer of diamonds remains. It is possible to mix the diamonds with an epoxide in a further alternative. If this mixture is applied on the second side of the substrate, or onto the side of the photosensor that is facing the second side of the substrate, then after the epoxide hardens this yields an epoxide resin layer there into which the diamonds are embedded. By these methods it is possible to manufacture substrates of all lengths, and thus it is also possible to implement the sensor for large measured sections.

To attain an even distribution of the diamonds in the substrate or in the layer, it is here preferred for their number-average particle size to be less than 1 μm. It is especially preferred for said particle size to be less than 100 nm.

If, however, the substrate consists of the diamond, then this is in particular a monocrystalline diamond.

The defect centres of the lattice defects function as magneto-optical transducers. In particular, the lattice defects are NV defects (nitrogen vacancy). The latter are a complex formation of a single nitrogen atom, which replaces a carbon atom in the carbon lattice of the diamond in connection with an immediately neighbouring defect of the carbon lattice. In an NV defect, therefore, instead of the two naturally present neighbouring carbon atoms in the lattice, a nitrogen atom is present in each case in the position of a carbon atom, and no atom at all is present in a further nearby position in each case. The diamond is preferably a diamond of the type Ib. In the latter, the nitrogen is not present in agglomeration, but is evenly distributed in substitutional lattice sites. On the one hand, when irradiated with light, the electron spin moment of the nitrogen defect centre is substantially completely polarised in the non-magnetic ground state. On the other hand, the NV defect emits light under excitation, wherein the number of photons depends on the spin state of the electron spin moment before irradiation.

An NV defect emits red fluorescent light when green light is irradiated into the diamond. For this purpose, the at least one light source is preferably equipped to emit light having a wavelength in the range of from 490 nm to 570 nm. For this purpose, said light source is in particular embodied as an LED. If the at least one light source is arranged on at least one third side, while the photosensor is arranged on the second side, the photosensor receives only the fluorescent light, and none of the light emitted by the at least one light source, due to total reflection of the irradiated light on another third side. The intensity of the received fluorescent light here depends on the magnetic field strength of a magnetic field acting on the diamonds.

In principle, each of the sides of the substrate is suitable for arranging one or several light sources. However, an arrangement on the first side makes positioning the sensor in a magnetic field position measuring system more difficult. Additionally, measures must here be put in place to ensure that light irradiated from the light source directly onto the photosensor does not interfere with the detection of the fluorescent light. If a light source is arranged on the second side, then its light can be reflected on the first side, and thus also be directed onto the photosensor. It is therefore preferred for the light source to be arranged on at least one third side of the substrate. It is especially preferred that at least one light source is arranged on each third side. An even emission of fluorescent light to all lattice defects results from the fact that light can be irradiated into the substrate from every third side. Thus, a magnetic field position measuring system that uses a sensor of this kind is free of hysteresis, and positions can be precisely approached from all sides.

In one embodiment of the sensor according to the invention, an optical reflection layer is arranged on the first side, said optical reflection layer being equipped to reflect light that falls through the substrate onto the reflection layer back into the substrate. A simple option for implementing a reflection layer of this kind is for the reflection layer to be a side of a housing of the sensor. This housing consists in particular of a metal. This embodiment is especially advantageous when diamonds are arranged in a layer between the substrate and the photosensor. Light that is emitted by the at least one light source is then reflected through the reflection layer in the direction of the second side, and thus in the direction of the diamonds.

For this purpose, it is further preferred that a direction of irradiation of the light source is angled in the direction of the first side if the light source is arranged on at least one of the third sides. This means that the angle of the direction of irradiation to the third side on which the light source is arranged is less than 90°.

It is additionally preferred for a colour filter to be arranged between the substrate and the photosensor. This colour filter should here be arranged in such a way that a layer of diamonds which may be present are located on the side of the colour filter facing away from the photosensor. Due to the reflection of the light emitted by the light source on the reflection layer, not only the fluorescent light, but the light emitted by the light source falls on the photosensor. It is an advantage of the colour filter that it can be embodied in such a way that the wavelength range of the light emitted by the light source is filtered out, such that only the fluorescent light reaches the photosensor. This enables the usage of a photosensor which is sensitive not only in the wavelength range of the fluorescent light, but in a greater wavelength range, and thus a photosensor with which the reception of light emitted by the light source would interfere.

Furthermore, it is preferred that a magnetic field generator is arranged around the substrate, in particular around its third sides. This magnetic field generator can in particular be embodied as at least one coil. Light sources which may be arranged on at least one third side are here surrounded by the coil. The generated magnetic field causes a Zeeman effect, which splits up a fluorescent signal of the fluorescent light into several signals of different wavelengths. This enables another evaluation of the sensor signal. Due to the Zeeman effect, the frequency drops depending on the applied frequency for another magnetic field strength. There is a defined magnetic field strength at which resonance occurs for every frequency. In combination with the photosensors using spatial resolution, it is thus possible to pass through individual frequencies, and, for each frequency, to check where the fluorescence drops on an active surface. The entire course of the magnetic field over the active surface can thus be determined.

The magnetic field generator is preferably equipped to emit microwaves. The magnetic flux density of the magnetic field is preferably at least 3 gauss, and in particular preferably at least 6 gauss.

It is further preferred that several interrupted parasitic coils are arranged in the coil. These generate a magnetic field in capacitively coupled coil portions via induction currents, said magnetic field counteracting the magnetic field generated by the magnetic field generator coil on the edges of the latter. The homogeneity of the magnetic field is thus improved, and thus an inhomogeneous splitting-up of the fluorescent signal is prevented.

The photosensor preferably has at least one sensor element, which is selected from a series of at least 8 photodiodes, a PSD (position-sensitive device), a CCD camera (charge-coupled device) and a CMOS camera (complementary metal oxide semiconductor). This enables the photocurrent generated by the fluorescent light to be laterally divided. A weighted mean averaging of the occurring fluorescent light thus occurs. In the case of a PSD, for example, this is enabled by the anode of the latter extending over the entire surface of the PSD, and by its two cathodes being connected only on two end faces. A sensitive axis from one end face to the other thus results. A CCD camera or a CMOS camera provide a digital signal along their entire sensitive axis. The photocurrent is not laterally split up, instead the entire fluorescent signal is present over the active surface of the CCD camera or the CMOS camera. To calculate a position, a weighted mean average value of the signal can in particular digitally be calculated, an auto-correlation function can be used, or a fitting algorithm can be used. In particular, not only the position of an individual magnet, but also the position of several magnets on an active surface can be determined when a CCD camera, CMOS camera or photodiode array is used. This can be used to read out a pseudo-random code (PRC) on a magnetic measuring body.

In this embodiment, it is preferred that the photosensor has several sensitive axes. A sensitive axis is understood as an axis along which one sensor signal can be detected. A PSD as sensor element emits an output signal at each of the two ends of its sensitive axis.

Two sensitive axes arranged in parallel to each other can here in particular have a phase shift to each other. Alternatively or additionally, two sensitive axes of the photosensor can be arranged orthogonally to each other. This can in particular be implemented via a two-dimensional PSD. In this way, a difference in the magnetisation transversely across a magnetised measuring body of the magnetic field position measuring system can be used.

The object is solved in a second aspect of the invention by a magnetic field position measuring system that has a sensor according to the first aspect of the invention. The first side of the sensor here faces towards at least one magnet, such that the latter functions as sensor head.

As, according to the first aspect of the invention, the sensor tolerates a greater air gap than is the case in conventional magnetic field position measuring systems, the magnetic field position measuring system according to the invention can be set up more easily than previously used magnetic field position measuring systems.

In one embodiment of the magnetic field position measuring system, said magnetic field position measuring system has a measuring body magnetised with changing polarity that faces towards the first side of the sensor. The measuring body can be embodied in the same way as the measuring body of a conventional magnetic field position measuring system that is in particular embodied as a magnetically coded length measuring system, and that is based on the AMR effect, the GMR effect or the TMR effect, or that uses Hall sensors. It is therefore also possible to retrofit a conventional magnetic field position measuring system as a magnetic field position measuring system according to the invention by replacing its sensor head with a sensor according to the first aspect of the invention, while the magnetised measuring body already present continues to be used.

The magnetised measuring body can, for example, have a pseudo-random code (PRC) in a track, said pseudo-random code being applied both orthogonally and in parallel to the direction of magnetisation of an incremental track of the measuring body. This in particular enables the determining of an absolute position of the sensor after it is turned on without a reference run being necessary for this purpose.

If the magnetic field position measuring system has a sensor according to the first aspect of the invention whose photosensor has a PSD, then if the sensor has two sensitive axes in parallel, a phase can be shifted between two signals of a PSD by changing the one breadth of the substrate and of the PSD when the pole width of the measuring body remains constant. The breadth of the substrate is understood as its measurement along the longitudinal axis of the measuring body.

In principle, every phase shift except 0°, 180° and 360° is possible in an embodiment of the magnetic field position measuring system having a PSD. However, the breadth of the substrate is preferably selected such that the phase shift between the signals is 90°.

If two PSDs are used as sensor elements, it is advantageous to select the substrate breadth and the breadth of the PSDs in such a way that a phase shift of around 180° results, such that the sensor signal is then present once normally and once inverted. A signal amplitude that is twice as high can be attained here via suitable relay than with only one sensor element. An offset and temperature effects can also be eliminated by subtracting the measuring signals of the two sensor elements.

The two elements should then preferably be arranged such that their output signals are in particular shifted at 90° to each other. Theoretically, however, every shift except 0°, 180° and 360° is possible.

If more than two PSD elements are used, these can be used to measure several poles of a magnetic measuring body simultaneously. Then errors can be corrected which occur when the magnetisation of a north pole of the measuring body is not identical with the magnetisation of the south pole. For this purpose, the output signals of the PSD elements can be switched in an analogue manner or cleared in digitalised form. A signal noise can be even further reduced by evaluating two poles of the measuring body.

When a CCD camera or a CMOS camera is used as a photosensor, the camera can be embodied at a length which covers several poles of the measuring body. This takes advantage of the fact that the camera provides not only the centre of the detected fluorescent signal, but also the shape of the signal.

In a further embodiment of the magnetic field position measuring system, the latter has a magnet which is movably arranged opposite an immovable sensor according to the first aspect of the invention. A direction of movement of the magnet can here run along a sensitive axis of the photosensor. Here, the magnet is in particular shorter than the sensitive axis.

Such a magnetic field position measuring system is in particular suitable for detecting the position of a magnet on a pneumatic cylinder.

The object is solved in a third aspect of the invention by a method for determining position by means of the magnetic field position measuring system according to the second aspect of the invention. In this method, light is irradiated into the diamonds by means of the at least one light source. Fluorescent light of the diamonds is converted into at least one output signal by means of the photosensor, and a position signal is generated from the at least one output signal. For this purpose, a trigonometric function can in particular be used.

To correct shifts of the substrate or light sources of different strengths, it is preferred that a calibration is made in which the electrical output currents of the photosensor are measured and corresponding correction values are defined without a magnetic field or with a defined magnetic field. A calibration of this kind can occur during the production of the magnetic field position measuring system or of its sensor, but also at a later point in time in the field.

A spacing between the first side of the sensor and a magnetised measuring body or a magnet can preferably be determined from an amplitude of the output signal. This takes advantage of the fact that the amplitude is an unambiguous function of the spacing between the sensor and the measuring body or the magnet. The spacing determined in this way can be used to help set up when arranging the sensor in the magnetic field position measuring system.

A spacing between the first side of the sensor and a measuring body can preferably be determined from an amplitude of the output signal. This takes advantage of the fact that the amplitude is an unambiguous function of the spacing between the sensor and the measuring body. The spacing determined in this way can be used to help set up when arranging the sensor on the measuring body.

If the magnetic field position measuring system according to the second aspect of the invention has a sensor whose photosensor has two sensitive axes, then it is preferred that a position signal is generated along the measuring body from an output signal of the first axis of said photosensor, and a position signal of a transverse offset to the measuring body is generated from an output signal of the second axis of said photosensor. Here, a difference in the magnetisation transversely over the measuring body can be used.

### BRIEF DESCRIPTION OF THE DRAWINGS

Exemplary embodiments of the invention are depicted in the drawings and are explained in more detail in the following description.

FIG. 1 shows a side view of a sensor in a magnetic field position measuring system according to an exemplary embodiment of the invention.

FIG. 2 shows a schematic depiction of a PSD of a sensor according to an exemplary embodiment of the invention.

FIG. 3 shows changes in the fluorescence of a diamond and output signals of a photosensor along a section in a method according to an exemplary embodiment of the invention in two diagrams.

FIG. 4 shows an overview of two sensors in a magnetic field position measuring system according to an exemplary embodiment of the invention.

FIG. 5 shows an isometric depiction of a sensor according to an exemplary embodiment of the invention.

FIG. 6 shows an isometric depiction of a sensor according to an exemplary embodiment of the invention.

FIG. 7 shows a cross-sectional depiction of a magnetic field position measuring system according to an exemplary embodiment of the invention.

FIG. 8 shows a cross-sectional depiction of a magnetic field position measuring system according to prior art.

FIG. 9 shows a cross-sectional depiction of a magnetic field position measuring system according to an exemplary embodiment of the invention.

FIG. 10 shows a cross-sectional depiction of a magnetic field position measuring system according to another exemplary embodiment of the invention.

FIG. 11 shows an overview of a sensor according to an exemplary embodiment of the invention.

FIG. 12a, b show fluorescence spectra of diamonds with and without exposure to a microwave field in two diagrams.

### EXEMPLARY EMBODIMENTS OF THE INVENTION

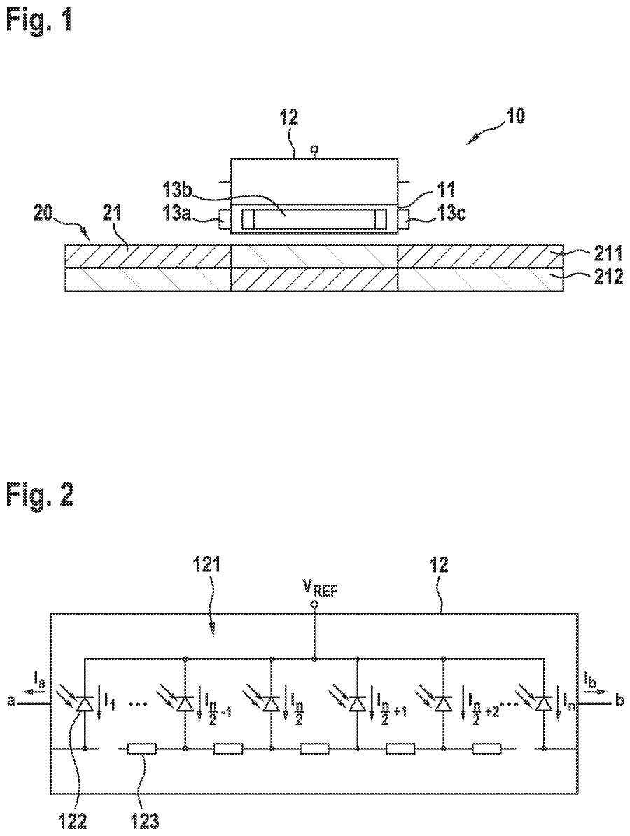

In a first exemplary embodiment of the invention depicted in FIG. 1, a magnetic field position measuring system that is embodied as a magnetic-coded length measuring system has a sensor 10 and a measuring body 20 magnetised with changing polarity. The sensor 10 comprises a substrate 11 having a length of 1.0 mm, a breadth of 1.0 mm and a height of 0.5 mm. The substrate 11 is a diamond having NV defects. The underside of this rectangular substrate 11 faces towards the measuring body 20 as a first side. The upper side of the substrate 11 faces away from the measuring body 20 as a second side. The four lateral surfaces of the substrate 11 represent its third sides. A photosensor 12 using spatial resolution is arranged on the second side. A light source is arranged on each of the four third sides in each case. This is depicted in FIG. 1 for three of the light sources 13a, 13b, 13c, while the fourth light source is not visible in the selected depiction. Each light source is embodied as an LED having a power of 25 mW, which emit light of a wavelength of 520 nm into the substrate 11.

The measuring body 20 has magnetisations 21 arranged with changing polarity along a direction of movement of the sensor 10. These alternatingly have a magnetic north pole 211 and a magnetic south pole 212.

The photosensor 12 is embodied as a PSD 121. This is depicted in FIG. 2. The PSD 121 has photodiodes 122 in an equivalent circuit diagram n. A reference voltage V_{REF} abuts on these. They are connected in parallel along the direction of movement of the sensor 10 along the magnetic measuring body 20, and thus form a sensitive axis. The photodiodes are connected to two cathodes a, b on the two ends of the PSD 121 via electrical resistances 226. An electrical current Iₐ on the first cathode a is obtained according to Formula 1:

$${I}_{a} = {\sum }_{i = 1}^{n} \frac{( n + 1 ) - i}{n} \cdot {I}_{i} \qquad ( Formula 1 )$$

Iᵢ here describes the current of the photodiodes 122 with the number i. The current I_{b} is obtained according to Formula 2:

$${I}_{b} = {\sum }_{i = 1}^{n} \frac{i}{n} \cdot {I}_{i} \qquad ( Formula 2 )$$

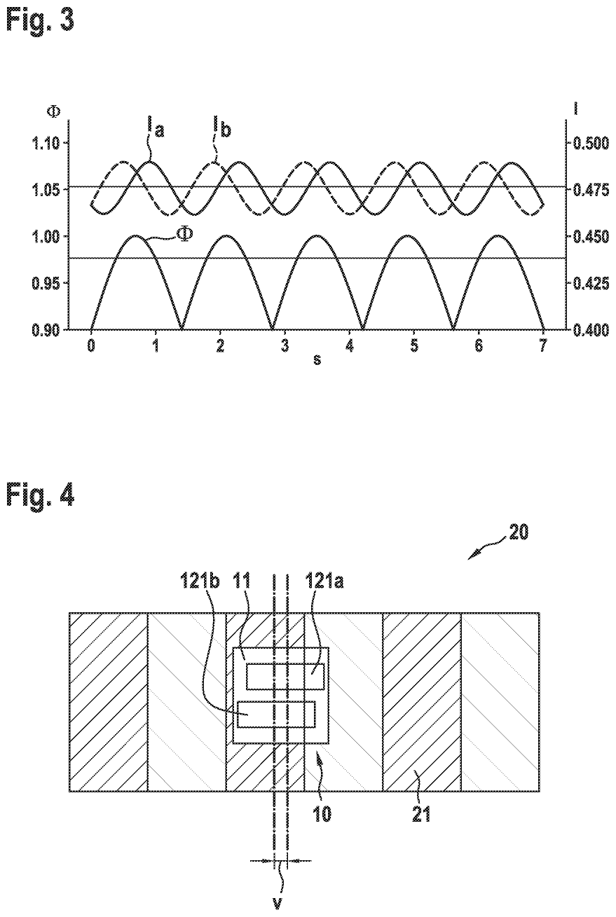

FIG. 3 shows that when light is irradiated into the substrate 11 by means of the light sources 13a, 13b, 13c, depending on the section s which was travelled along the measuring body 20, a fluorescence φ of the diamond results, which is detected by the PSD 121 and converted into two output signals in the form of the electrical currents Iₐ, I_{b}. Here the first current 1ₐ shows a sinusoidal course and the second current I_{b} shows a co-sinusoidal course. The two currents Iₐ, I_{b} are thus phase-shifted by 90°. Each of the output signals is the result of a weighted mean average of the entire light surface of the substrate 11. In this way, it has very little noise. The output signals are evaluated to a position signal by means of a transimpedance amplifier and a digital signal processing, in order thus to determine the position of the sensor 10 along the measuring body 20 and to output this to a user.

In a second exemplary embodiment of the invention depicted in FIG. 4, the sensor 10 has a substrate 11 that is not completely covered by a single PSD 121. Instead, two PSDs 121a, 121b are arranged next to each other on the substrate 11 in such a way that their sensitive axes run in parallel. The lengths of the PSDs 121a, 121b, for example of 0.7 mm each, are selected such that when the breadth of the magnetisations 21 is 1.0 mm, the two currents Iₐ, I_{b} of each of the PSDs 121a, 121b are phase-shifted to each other by 180°, such that in terms of amount they add up to a total current value of Iₜₒₜ=|Iₐ|+|I_{b}|, which has a signal amplitude that is twice as large as a signal amplitude of the currents Iₐ, I_{b} alone at every point of the section s. The two PSDs 121a, 121b are shifted against each other along their sensitive axes by a shift v, such that the two total current values Iₜₒₜ of the two PSDs 121a, 121b are shifted to each other by 90°. Two signal courses can thus be obtained which have the same phase shift as the two signal courses in FIG. 2, but show higher signal intensities.

The spacing between the second side of the sensor 10 and the measuring body 20 can be more than 100% of the breadth of the magnetisations 21 in all exemplary embodiments, without the functionality of the magnetic field position measuring system being compromised as a result. It is thus superior to other magnetic field position measuring systems embodied as magnetically coded length measuring systems, which use a Hall sensor, for example. In magnetic field position measuring systems of the kind of prior art, the spacing between the Hall sensor and the measuring body may not be more than 50% of the breadth of the magnetisations 21.

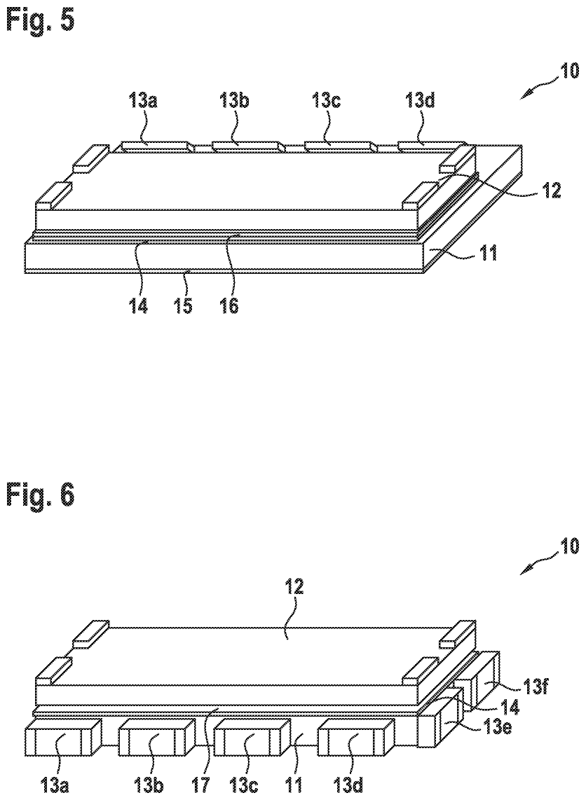

In a third exemplary embodiment of the invention shown in FIG. 5, a sensor 10 has a substrate 11 that consists, for example, of glass. In this exemplary embodiment too, the underside of the substrate 11 represents the first side, which is provided to face towards at least one magnet in a magnetic field position measuring system.

On the second side opposite the first side, a photosensor 12 using spatial resolution is arranged, which is embodied as a PSD. The substrate 11 is rectangular, and therefore has four further sides that are described as third sides. Four light sources 13a-d are arranged on one of these third sides. Each light source is embodied as an LED having a power of 25 mW, which emits green light of a wavelength of 520 nm into the substrate 11. Each of the light sources is here arranged such that their direction of irradiation into the substrate 11 is angled at 45° to the third side on which the light sources 13a-d are arranged. The light sources 13a-d thus irradiate light in the direction of the second side of the substrate 11 into said substrate. Diamonds 14 having NV defects are arranged in a layer on the upper side of the substrate 11, underneath the photosensor 12. A reflection layer 15 made of a metal, which represents a part of a metal housing of the sensor 10, is arranged on the first side. A colour filter 16 is arranged between the diamonds 14 and the photosensor 12, which absorbs light of a wavelength of 520 nm. It is permeable for red light, however.

When the sensor 10 is operating, the light sources 13a-d irradiate green light into the substrate 11. This hits the reflection layer 15, and is reflected by the latter in the direction of the second side, and thus in the direction of the diamonds 14. A part of the light induces the diamonds 14 to fluoresce. The remaining light hits the colour filter 16, and is absorbed by the latter. The diamonds 14 emit red fluorescent light, which passes the colour filter 16 unhindered, is received by the photosensor 12 and is converted into an electrical output signal.

A fourth exemplary embodiment of the sensor 10 according to the invention is depicted in FIG. 6. A substrate 11 that, as in the second exemplary embodiment, can for example consist of glass, also has a first side, a second side and four third sides. Several light sources are arranged on each of the third sides. This is depicted in FIG. 6 for six light sources, wherein four light sources 13a-d are arranged on one of the third sides, and two further light sources 13e-f are arranged on another of the third sides. The light sources on the remaining two third sides cannot be seen in the depiction in FIG. 6. As in the two previous exemplary embodiments of the sensor 10, the substrate 11 has a photosensor 12 using spatial resolution on its second side in the form of a PSD. A layer of diamonds 14 having NV defects is arranged on the second side of the substrate 11 such that it is between the substrate 11 and the photosensor 12. In place of the colour filter 16 according to the first exemplary embodiment of the sensor 10, an air gap 17 is arranged between the photosensor 12 and the diamonds 14.

All light sources 13a-f, which emit green light of a wavelength of 520 nm as in the first exemplary embodiment, are arranged such that they emit their light into the substrate 11 in parallel to the second side. A part of the light is here directed onto the diamonds 14 via reflections on the third side of the substrate 11. Light that does not induce the diamonds 14 to total fluorescence in the process hits the air gap 17 instead, and is thrown back into the substrate 11 via a total reflection. The fluorescent light of the diamonds 14 passes the air gap 17, however, and hits the photosensor 12. It is converted into an electrical output signal by this photosensor as in the first exemplary embodiment of the sensor 10.

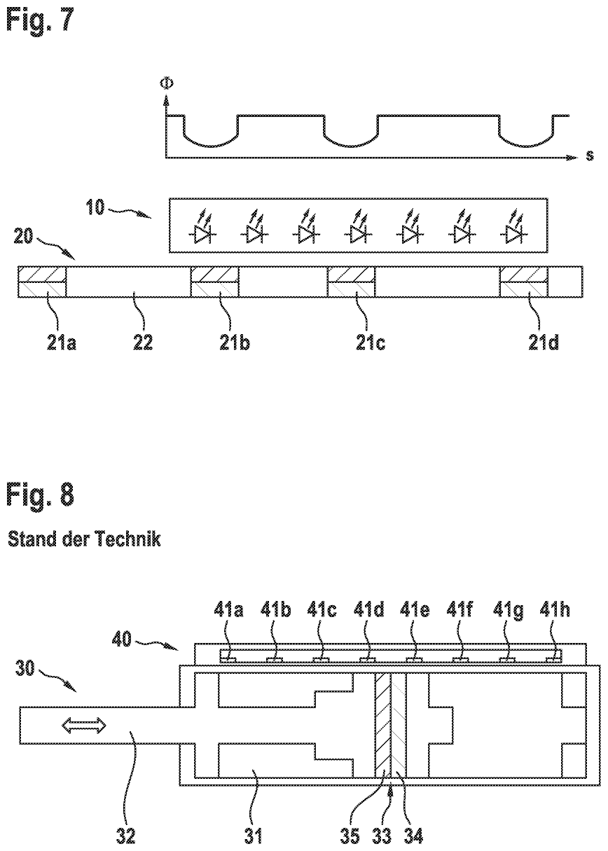

FIG. 7 shows a magnetic field position measuring system in a fifth exemplary embodiment of the invention. A sensor 10 is arranged above one of the magnetised measuring bodies 20 according to the second or third exemplary embodiment in such a way that the first side of the sensor 10 faces towards the measuring body 20. The measuring body 20 here has a carrier 22 in which four magnets 21a-d are arranged. The magnets 21a-d are embodied as permanent magnets whose north poles each face towards the sensor 10. In the position depicted in FIG. 7, the first magnet 21a is not arranged under the sensor 10, and the following three magnets 21b-d are arranged under the sensor 10. The course of the fluorescence ϕ of the diamonds 14 along the section s of the sensitive axis of the photosensor 12 is depicted in a diagram. It can be seen that the fluorescence ϕ sinks at each of the positions of these three magnets 21b-d due to the influence of the magnetic field of the three magnets 21b-d on the fluorescent behaviour of the diamonds 14. If, for example, the photosensor 12 is embodied as a CMOS camera, and the measuring body 20 has an PRC code (not depicted in FIG. 7) that codifies an absolute position on a side of its material measure, then the PRC code can be read out by means of the sensor 10.

FIG. 8 shows a pneumatic cylinder 30 of a pneumatic actuator that is equipped with a conventional magnetic field position measuring system 40. The pneumatic cylinder 30 has a cylinder chamber 31 in which a piston 32 can be moved. The piston 32 has a magnet 33 for determining its position. This magnet has a north pole 34 and a south pole 35 along its direction of movement. The conventional sensor 40 is arranged along the entire length of the cylinder chamber. The sensor has 8 Hall sensors 41a-h distributed over this length, by means of which the position of the magnet 33, and thus the position of the piston 32, can be determined. The conventional sensor 40 does not enable a continuous position measurement here, however, but only the recognition of that position of the piston 32 in which one of the Hall sensors 41a-h is located.

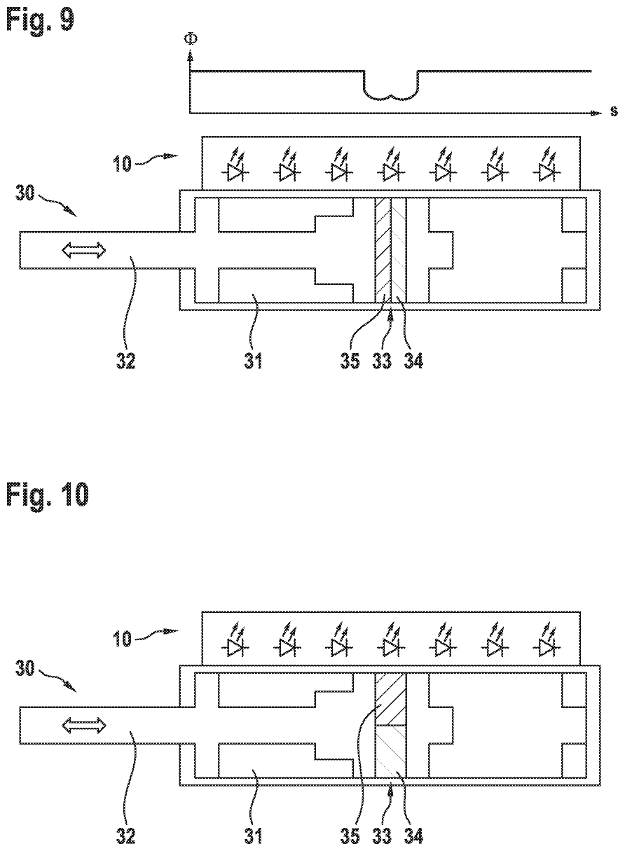

In a sixth exemplary embodiment of the invention, it is provided that the conventional sensor 40 of the magnetic field position measuring system is replaced by a sensor 10 according to the second or third exemplary embodiment. This is depicted in FIG. 9. It is thus possible to continually determine a position of the piston 32. The fluorescent behaviour of the diamonds 14 is influenced by the magnets 33 in characteristic manner as depicted in a diagram in FIG. 9. A reduction of the fluorescence ϕ occurs at the position of the magnet 33 along the section s of the sensitive axis of the photosensor 12. Two local minima here occur, which correspond to the particular position of the north pole 34 and the south pole 35 of the magnet 33.

In a seventh exemplary embodiment of the invention, it is provided that the polarisation of the magnet 33 is turned by 90° relative to the sixth exemplary embodiment. In this way, only one pole 35 faces towards the sensor 10. In this exemplary embodiment too, it is possible to continually determine the position of the piston 32.

A sensor 10 according to an eight exemplary embodiment of the invention is depicted in FIG. 11. This sensor has a substrate 11 that consists, for example, of polycarbonate, in which diamonds having a number-average diameter of 25 nm are distributed. The diamonds have NV defects. The first side, the second side and the third sides of the substrate 11 are defined in the same manner as in the previous exemplary embodiments. A photosensor 12 using spatial resolution embodied as a PSD is arranged on the second side, and two LEDs are arranged as light sources 13a-h on each of the third sides in each case. The first side is provided for the purpose of facing towards a magnetic measuring body. The light sources 13a-h are surrounded by a magnetic field generator 50 in the form of a coil. Two interrupted coils 60a, 60b are arranged between the coil 50 and the light sources 13a-h. The coil 50 generates a magnetic field of 7.5 gauss, for example, by generating microwaves having a frequency of 2.87 GHz, for example.

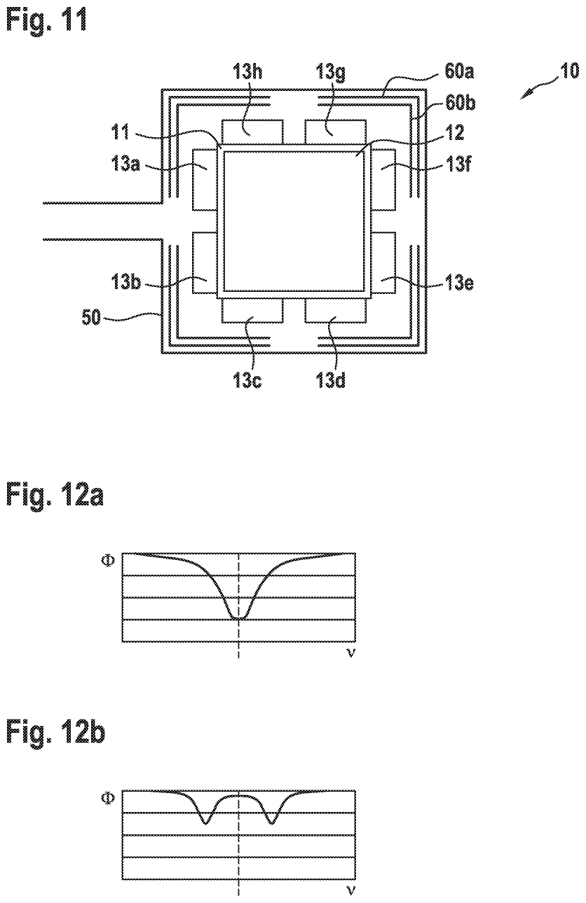

FIG. 12a shows a fluorescent signal of the substrate 11, which is depicted without influence of an external magnetic field, wherein the fluorescence ϕ is applied over the frequency v. When the microwave source is switched on, a splitting up of the fluorescent signal at 42 MHz occurs such that the fluorescent signal results according to FIG. 12b.

1. Sensor (10) for a magnetic field position measuring system, said sensor comprising: at least one transparent substrate (11) having a first side and a second side opposite to the first side,
at least one photosensor (12) using spatial resolution arranged on the second side of the least one transparent substrate,
at least one light source (13a-h) arranged on at least one side, and
diamonds (14) having lattice defects arranged between the substrate (11) and the photosensor (12) and/or diamonds (14) having lattice defects arranged in the substrate (11) and/or the substrate (11) is a diamond having lattice defects.

2. The sensor (10) according to claim 1, wherein the lattice defects are nitrogen vacancy defects.

3. The sensor (10) according to claim 1 wherein the light source (13a-h) is arranged on at least one third side of the substrate (11).

4. The sensor (10) according to claim 3, wherein at least one light source (13a-h) is arranged on each third side.

5. The sensor (10) according to claim 1, wherein an optical reflection layer (15) is arranged on the first side.

6. The sensor (10) according to claim 5, wherein the optical reflection layer (15) is a side of a housing of the sensor (10).

7. The sensor (10) according to claim 6, wherein a direction of irradiation of the light source (13a-h) is angled in the direction of the first side.

8. The sensor (10) according to one of claim 5, wherein a colour filter (16) is arranged between the substrate (10) and the photosensor (12).

9. The sensor (10) according to claim 3, wherein an air gap (17) is arranged between the substrate (10) and the photosensor (12).

10. The sensor (10) according to claim 1, wherein a magnetic field generator (50) is arranged around the substrate (11).

11. The sensor (10) according to claim 1, wherein the photosensor (12) has at least one sensor element, which is selected from a series of at least 8 photodiodes, a PSD (121), a CCD camera and a CMOS camera.

12. The sensor (10) according to claim 11, wherein the photosensor (12) has a sensor element that is equipped to provide each of a first output signal (Iₐ) and a second output signal (I_{b}), which have a phase shift to each other which is not 0°, 180° or 360°.

13. The sensor (10) according to claim 11, wherein the photosensor (12) has several sensitive axes.

14. The sensor (10) according to claim 13, wherein the photosensor (12) has two sensor elements that are equipped to provide each of a first output signal (Iₐ) and a second output signal (I_{b}), which are phase shifted to each other by 180°, wherein the two first output signals (Iₐ) have a phase shift to each other which is not 0°, 180° or 360°, wherein the sensor elements form two sensitive axes of the photosensor (12) in parallel.

15. The sensor (10) according to claim 13, wherein the two sensitive axes of the photosensor (12) are arranged orthogonally to each other.

16. The sensor according to claim 1, wherein the sensor is in a magnetic field position measuring system.

17. The sensor according to claim 16, wherein the magnetic field position measuring system has a measuring body (20) magnetised with changing polarity that faces towards the first side of the sensor (10).

18. The sensor according to claim 16, wherein the magnetic field position measuring system has a magnet (33), which is movably arranged opposite the sensor (10), wherein the sensor (10) is immovable.

19. Method for determining position by means of a magnetic field position measuring system having a sensor comprising at least one transparent substrate having a first side and a second side opposite to the first side, at least one photosensor using spatial resolution arranged on the second side of the least one transparent substrate (11), at least one light source arranged on at least one side, and diamonds having lattice defects arranged between the substrate and the photosensor and/or diamonds having lattice defects arranged in the substrate and/or the substrate is a diamond having lattice defects, the method comprising:
irradiating light into the substrate (11) by means of the at least one light source (13a-h),
converting fluorescent light (Φ) into at least one output signal (Iₐ, I_{b}) by means of the photosensor (12), and
generating a position signal from the at least one output signal (Iₐ, I_{b}).

20. Method according to claim 19, wherein two output signals (Iₐ, I_{b}) of a sensor element are each added to generate the position signal.

21. Method according to claim 19, wherein a spacing between a first side of the sensor (10) and a measuring body (20) is determined from an amplitude of the output signal (Iₐ, I_{b}).

22. Method according to claim 20, wherein the magnetic field position measuring system has a sensor (10) wherein the two sensitive axes of the photosensor (12) are arranged orthogonally to each other, wherein a position signal is generated along the measuring body (20) from an output signal (Iₐ, I_{b}) of its first axis, and a position signal of a transverse offset to the measuring body (20) is generated from an output signal of its second axis.
